(19) United States
(12) Patent Application Publication
(10) Pub. No.: US 2014/0048799 A1
(43) Pub. Date: Feb. 20, 2014

(54) INVISIBLE/TRANSPARENT NONVOLATILE MEMORY

(71) Applicants: James M. Tour, Bellaire, TX (US); Jun Yao, Houston, TX (US)

(72) Inventors: James M. Tour, Bellaire, TX (US); Jun Yao, Houston, TX (US)

(73) Assignee: William Marsh Rice University, Houston, TX (US)

(21) Appl. No.: 13/985,956

(22) PCT Filed: Feb. 16, 2012
(86) PCT No.: PCT/US12/25435

§ 371 Date: Nov. 4, 2013

Related U.S. Application Data
(60) Provisional application No. 61/443,420, filed on Feb. 16, 2011.

(51) Int. Cl. H01L 45/00

(52) U.S. Cl. CPC H01L 45/145; H01L 45/1608
USPC 257/43; 438/382

(57) ABSTRACT

An optically transparent memory device comprises first and second electrodes, wherein the electrodes are formed from conductive material(s) that is transparent. The memory device also provides a resistive memory layer coupled to the first and second electrodes. The resistive memory layer is formed from a resistive memory material providing resistive switching that is transparent. Additionally, the optically transparent memory device may be incorporated into a variety of electronics.

### RELATED APPLICATIONS

This application claims the benefit of U.S. Provisional Patent Application No. 61/443,420, filed on Feb. 16, 2011. The entirety of the above-referenced application is incorporated herein by reference.

### STATEMENT REGARDING FEDERALLY SPONSORED RESEARCH

This invention was made with government support under United States Army Grant No. W911NF-08-C-0133, awarded by the U.S. Department of Defense; United States Air Force Grant No. FA9550-10-C-0098, awarded by the U.S. Department of Defense; and United States Navy Grant No. N00039-10-0056, also awarded by the U.S. Department of Defense. The government has certain rights in the invention.

### FIELD OF THE INVENTION

Invisible/transparent nonvolatile memory devices are discussed herein. More particularly, memory devices that are transparent regardless of memory density are provided herein.

### BACKGROUND OF INVENTION

Electronic memory is the carrier for information storage, thus a key component in electronics. The realization of transparent memory may be desirable for integrated transparent electronics. While some individual memory bits/units can be invisible to the eye based upon their small size, as the bit/unit density increases, the visibility of the system becomes apparent because opaque silicon or opaque metal wiring are used throughout the structure.

If transparent materials are utilized for the entire design, then the entire memory would be transparent, regardless of the density. Transparent memory devices may allow the development of transparent electronics, such as, but not limited to, transparent displays with memory embedded in the display itself, touch screen displays, memory-containing visors, windscreens, and the like, including smart “heads-up” displays and “smart-windows”, with embedded memory or logic, memory arrays, transistors, microelectronics, nanoelectronics, and other electronic devices that utilize memory.

### SUMMARY OF THE INVENTION

In one implementation, an optically transparent memory device comprises first and second electrodes, wherein the electrodes are formed from conductive and transparent material(s). The memory device also provides a resistive memory layer coupled to the first and second electrodes. The resistive memory layer is formed from a resistive memory material that is transparent. In some implementations, the memory device may be placed on a transparent substrate. In some implementations, the resistive memory layer may be positioned between the two electrodes to form a vertically stacked arrangement. In other implementations, the electrodes may be positioned on the resistive memory layer with a nanogap separation to form a horizontal arrangement.

Electrodes may be formed of any suitable conductive material, or a combination of conductive materials, that is also transparent. Non-limiting examples include graphene, indium tin oxide (ITO), transparent conducting oxides, fluorine doped tin oxide (FTO), doped zinc oxide, aluminum-doped zinc-oxide (AZO), indium-doped cadmium-oxide, transparent conducting polymers, polyacetylene, polyaniline, polypyrrole, polythiophenes, and/or nanocarbon coatings.

Resistive memory layers may be formed of any suitable resistive memory material, or a combination of resistive memory materials, that is also transparent. Non-limiting examples include SiOₓ, SiOₓN_{y}, SiOₓC_{z}, SiOₓH, SiOₓN_{y}H, SiOₓC_{z}H or the like. In some implementations of SiOₓ, x is greater than or equal to 0.5 or less than or equal to 2. More preferably, in other implementations, x is greater than or equal to 1 or less than or equal to 2. In some implementations, y is greater than or equal to 0 or less than or equal to 1.33. In some implementations, z is greater than or equal to 0 or less than or equal to 1. In another implementation, each of x, y and z are equal or greater than 1 or equal or less than 2.

The foregoing has outlined rather broadly various features of the present disclosure in order that the detailed description that follows may be better understood. Additional features and advantages of the disclosure will be described hereinafter.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIG. 1 is an illustrative implementation of a transparent memory unit providing a sandwiched structure in a two-terminal configuration;

FIG. 2 is an illustrative implementation of fabrication of a TE/TML/TE memory unit, where TE is a transparent electrode and TML is a transparent memory layer;

FIG. 3 is a illustrative implementation of a transparent memory unit in a planar configuration;

FIG. 4A and FIG. 4B show (a) memory cycles for a TE/TML/TE device and (b) an image of invisible memory units on poly(ethylene terephthalate) (PET) plastic;

FIG. 5A and FIG. 5B are illustrative implementations of (a) a transparent memory system providing multiple memory units on a transparent substrate and (b) a close up view of a memory unit;

FIG. 6A and FIG. 6B show (a) Raman spectrum (Excitation: 514 nm) of the graphene film and (b) transfer characteristic of a graphene-stripe field effect device;

FIG. 7 is a schematic of a fabrication process for a G/SiOₓ/ITO device, where G is graphene;

FIG. 8 is a schematic of a fabrication process for a G/SiOₓ/G device;

FIG. 9 shows an electroforming process for a vertical G/SiOₓ/ITO device;

FIG. 10A and FIG. 10B show SEM images of (a) a G/SiOₓ/ITO devices and (b) a control SiOₓ/ITO devices without top graphene layers;

FIGS. 11A-11E show (a) a G/SiOₓ/ITO device array on a glass substrate and a setup for electrical characterization; (b) an optical image of a G/SiOₓ/ITO device; (c) I-V curves from an electroformed G/SiOₓ/ITO device; (d) a series of voltage pulses of +6 V, +1 V, and +14 V serve as set, read, and reset operations; (e) memory cycles in a G/SiOₓ/ITO device; and (f) retention of memory states tested by continuous +1 V voltage pulses (at a rate of 1 pulse per sec) for both an ON and an OFF state;

FIGS. 12A-FIG. 12D show (a) a G/SiOₓ/G device on glass (b) optical transmittance in G/SiOₓ/G layered structures with different layer thicknesses of graphene (c) the typical I-V curves from an electroformed G/SiOₓ/G device and (d) the corresponding memory cycles;

FIGS. 13A-13D show (a) an enlarged view of a crossbar structure and (b) an optical image of a 4×4 G/SiOₓ/G crossbar structure; (c) characteristic I-V curves from an electroformed crossbar memory unit; and (d) memory cycles from a device using +5 V and +15 V as set and reset voltages; and

FIGS. 14A-14D show (a) a G/SiOₓ/G device array on a plastic (fluoropolymer) substrate; (b) an optical image of the arrays; (c) characteristic resistive switching I-V curve from a G/SiOₓ/G device on the plastic substrate; and (d) retention of both ON (sub a) and OFF (sub b) memory states upon bending the plastic substrate around a ˜1.2-cm diameter curvature (photo inset).

### DETAILED DESCRIPTION

Refer now to the drawings wherein depicted elements are not necessarily shown to scale and wherein like or similar elements are designated by the same reference numeral through the several views.

Referring to the drawings in general, it will be understood that the illustrations are for the purpose of describing particular implementations of the disclosure and are not intended to be limiting thereto. While most of the terms used herein will be recognizable to those of ordinary skill in the art, it should be understood that when not explicitly defined, terms should be interpreted as adopting a meaning presently accepted by those of ordinary skill in the art.

It is to be understood that both the foregoing general description and the following detailed description are exemplary and explanatory only, and are not restrictive of the invention, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that comprise more than one unit unless specifically stated otherwise.

Transparent or invisible electronics may be desirable in the future generations of electronics. Electronic memory is the carrier for information storage, thus a key component in electronics. The realization of transparent memory is desirable for integrated transparent electronics. Though individual memory bits/units can be invisible to the eye based upon their small size, as the bit/unit density increases, the visibility of the system becomes apparent because opaque silicon and opaque metal wiring are used throughout the structure.

Potential technological advances from “invisible” or visibly transparent circuits have aroused extensive interest and motivated various studies in this direction. Progress has been made by using wide-bandgap semiconductors or nanowires to construct transparent transistors. For the realization of a fully integrated invisible circuit, high transparency is also desirable in one of the other indispensable circuitry elements: the memory unit. Although charge-based transparent memory can be constructed based on the transistor structure, it comes with the tradeoff in nonvolatility due to the limitations in achieving both high transparency and efficient charge trapping in the floating gate. This sacrifice can be eliminated by using resistive switching memory that can function on a non-charge based mechanism, provided that transparency is achieved both in the resistive memory material(s) and the electrodes.

While metal oxides or organic materials may potentially be suitable, a high-transparency memory device based on materials more suitable from the perspectives of processing and application is desirable. Using a transparent memory layer and transparent electrodes, a nonvolatile memory device featuring both high transparency and robust retention is provided. This transparent memory device may be optionally placed on transparent and/or flexible substrates.

For optical transparency without sacrificing the memory density or capacity, intrinsic transparency is desired in transparent memory systems. This may preclude many resistance-change materials with a bandgap <3.1 eV. The transparency can be further compromised by the top and bottom electrodes. For this reason, although transparent solid electrolytes can be involved in some metallic programmable cells, the use of a metal electrode as the filament-injection source limits the transparency in the device unit. Similarly, the requirement of a specific electrode-material interface in some resistive switching systems may restrict the choice of transparent electrode materials.

A non-limiting example of a resistive memory material providing resistive switching is SiOₓ. The intrinsic memory switching in SiOₓ enables the construction of completely metal-free transparent memory devices by using a transparent electrode material, such as graphene. For the fast progress in synthesis and abundance in the carbon sources, graphene has become a promising candidate for transparent electrode materials. The use of graphene and SiOₓ, another low-cost and industry-standard material, as materials for constructing memory devices provides advantages both in the material composition and processing.

Transparent resistive memory materials are capable of providing resistance changes and are also intrinsically transparent. For example, after initialization or electroforming, a resistive memory material may be capable of providing multiple conductivity states. A non-limiting example of a resistive memory material is SiOₓ. Because SiOₓ is intrinsically transparent and provides intrinsic memory effects, it may be a material suitable for use in transparent nonvolatile memory systems. The intrinsic memory effects in SiOₓ permit the use of transparent electrode materials, such as graphene, ITO, or the like, as TE to form TE/TML/TE memory units, where TML represents the transparent memory layer. The resulting memory unit features intrinsic transparency and simple structure in a two-terminal configuration, both of which may be desirable for a high-density transparent memory. Moreover, these transparent memories can be built upon a transparent substrate if used in conjunction with transparent wiring.

The x value in SiO, can be varied for desired performance. For example, in some embodiments, x is greater than or equal to 0.5 and less than or equal to 2. In other implementations, x is more preferably greater than equal to 1 or less than or equal to 2. An annealing process may be adopted to facilitate the initialization/electroforming process. Different etching methods (or recipes) may potentially lead to performance variations by introducing different defects at the vertical edges.

Note that since silicon filaments through direct Si—Si bond formation are likely to be responsible for the memory effect, other transparent materials with Si and O elements may be utilized as the transparent resistive memory material, such as SiOₓN_{y}, SiOₓC_{z}, SiOₓH, SiOₓN_{y}H, SiOₓC_{z}H, or the like. In some embodiments, the y ratio of N_{y} to Si is in the range from 1.33 to 0. In some embodiments, the z ratio of C_{z} to Si is in the range from 1 to 0. In some embodiments, each of x, y and z are equal or greater than 1 or equal or less than 2.

A transparent memory layer contains at least one transparent resistive memory material. In some implementations, the transparent memory layer may contain multiple layers of transparent resistive memory materials, where the transparent resistive memory materials are the same or a combination of different resistive memory materials. The thickness of the transparent memory layer can be varied for desired performance.

Transparent resistive memory materials also allow the use of transparent electrode materials to form the conductive contacts. The transparent electrodes may be any suitable transparent conducting material, such as graphene, ITO, transparent conducting oxides, FTO, doped zinc oxide, AZO, indium-doped cadmium-oxide, transparent conducting polymers, polyacetylene, polyaniline, polypyrrole or polythiophenes, nanocarbon coatings, and the like. Transparent electrodes may be either symmetrical (same materials for both electrodes) or asymmetrical (different materials for the two electrodes).

The transparent resistive memory material may be coupled to transparent electrodes in any suitable arrangement, such as, but not limited to, a TE/TML/TE structure, where TE is a transparent electrode and TML is a transparent memory layer, or planar arrangement. Moreover, in some implementations, the transparent memory may be disposed on a transparent substrate. The transparent substrate may be any suitable insulating material that is transparent, such as glass, plastic, polymer(s), fluoropolymer(s), perfluoroalkoxy (PFA), poly(ethylene terephthalate), poly(methyl methacrylate) (PMMA), and/or the like. In some implementations, the materials of the transparent memory unit and/or the thickness of components may be selected to provide flexibility.

In some implementations, a single memory unit may be suitable for multi-bit storage. In some implementations, the memory is operated at certain level of vacuum or oxygen deficient environment. Non-limiting examples may include one or more inert gases, such as N₂ and Ar. Standard industrial hermetic sealing techniques may be utilized to provide such an environment.

Optically transparent may include the range from 400 nm to about 800 nm in wavelength. Measurement of the optical transparency are provided at 550 nm, but similar levels of transparency are generally desired throughout the optical range. In some implementations, the memory has greater than 30% transparency at 550 nm. In some implementations, the memory has greater than 50% transparency at 550 nm. In some implementations, the memory has greater than 90% transparency at 550 nm. In some implementations, the first electrode or second electrode have greater than about 30% transparency at 550 nm. In some implementations, the first electrode or second electrode have greater than about 50% transparency at 550 nm. In some implementations, the first electrode or second electrode have greater than about 90% transparency at 550 nm.

Transparent memory systems and methods are suitable for use in electronic devices in which transparency is desired. Non-limiting examples of uses in electronic devices may include transparent displays with transparent memory embedded in the display itself; touch screen displays with transparent memory; transparent memory-containing visors, windscreens, and/or the like including smart “heads-up” displays or “smart-windows” with embedded memory and/or logic; transparent memory arrays; transparent memories integrated transistors; transparent memories integrated microelectronics; transparent memories integrated nanoelectronics; and/or various other electronic applications.

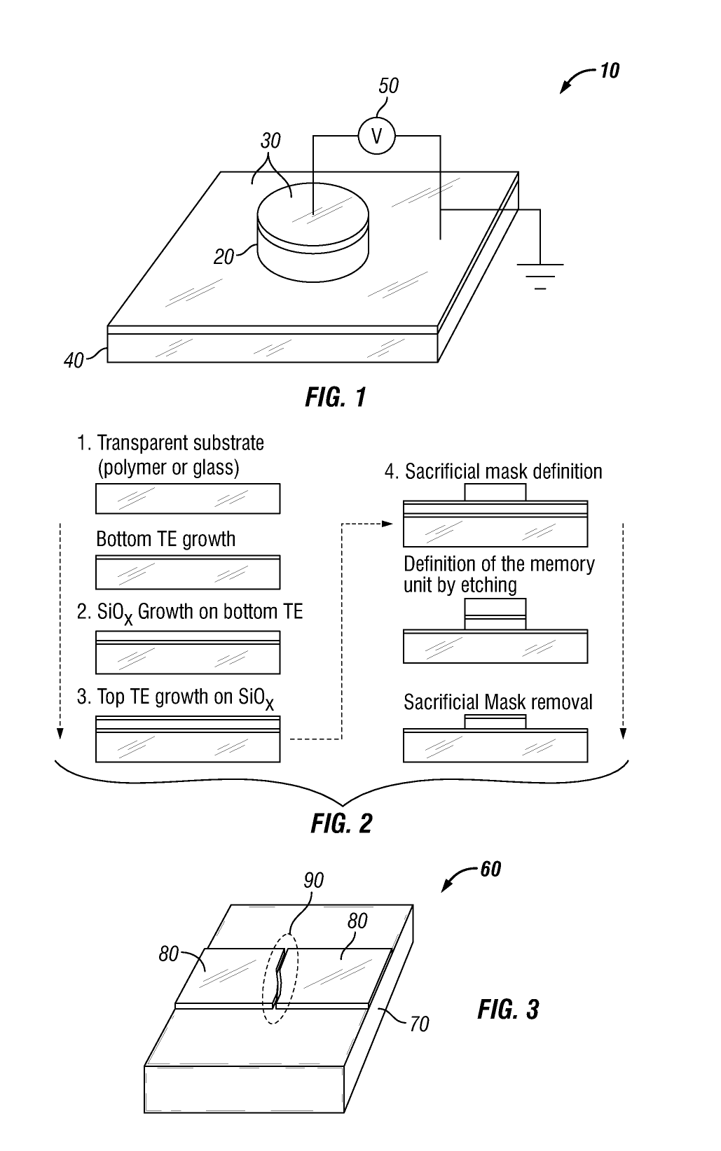

FIG. 1 is an illustrative implementation of a transparent memory unit 10 adopting a sandwiched structure in a two-terminal configuration. The transparent memory unit illustrated utilizes a transparent memory layer 20 formed from transparent memory material(s). The transparent memory layer 20 is sandwiched between transparent electrodes 30 to form a TE/TML/TE structure. Arrays of individual transparent memory units may be formed in an addressable manner. In FIG. 1, transparent memory layer 20 is formed from SiOₓ. However, in other implementations, any suitable transparent memory material(s) may be substituted. Transparent electrodes 30 can be made of any transparent conducting materials (non-limiting examples may include graphene, ITO, and/or the like). Transparent memory unit 10 provides a two-terminal configuration, as opposed to a three-terminal configuration. The transparent memory layer 20 can be grown by any suitable method, such as chemical vapor deposition (CVD), low pressure chemical vapor deposition (LPCVD), plasma enhanced chemical vapor deposition (PECVD), thermal oxidation, electron-beam evaporation, physical sputter deposition, reactive sputter deposition, spin-coating followed by curing, or any other suitable deposition process.

In some implementations, the memory units or memory arrays may be supported by a transparent substrate 40, such as glass, plastic, polymer(s), fluoropolymer(s), perfluoroalkoxy (PFA) polymers, poly(ethylene terephthalate), or the like. A voltage 50 may be applied to electrodes 30 to read or write transparent memory unit 10.

Once initialized/electroformed, the conductance of the TE/TML/TE unit can be modulated by voltage pulses of different magnitudes. For example, a moderate voltage pulse (e.g., 3-6 V) can set the unit into a low-resistance (ON) state while a higher voltage pulse (e.g., >7 V) can reset the unit to a high-resistance (OFF) state. It will be recognized by one of ordinary skill in the art that these resistance (or conductance) states can serve as the binary code 0 and 1 in digital information. Once programmed, the resistance states (both ON and OFF states) are nonvolatile. The memory reading operation occurs at a lower voltage (e.g., <3V) utilizing the same electrodes as write operations. Further, the memory state can be read nondestructively.

FIG. 2 is an illustrative implementation of fabrication of a TE/TML/TE memory unit. The fabrication steps may include the following steps:

Bottom TE (e.g., graphene, ITO, or the like) deposition on a transparent substrate (e.g., glass, plastic, polymer, or the like).

Transparent memory layer (TML) is deposited on the bottom TE layer. As a non-limiting example, a SiO, (1≦x≦2) layer is deposited on the bottom TE in the fabrication shown.

Top TE deposition on the transparent memory layer.

Sacrificial mask definition by lithography, followed by etching process to define the memory units.

FIG. 3 is a illustrative implementation of a transparent memory unit 60 in a planar configuration. Transparent memory unit 60 provides a transparent substrate 70 with transparent electrodes 80 separated by a nanogap 90. In some implementations, the nanogap may be as small as sub-1-nm in size to as large as about 100 nm in size.

As a non-limiting example, transparent substrate 70 may be formed from SiOₓ, and transparent electrode 80 may be formed from graphene, ITO, and/or the like. Once initialized/electroformed, the conductance of the transparent memory unit 50 can be modulated by voltage pulses of different magnitudes, and can be read at low voltage.

Transparent memory systems may feature the following properties:

Intrinsic transparency: since the memory effect is intrinsic to the transparent memory materials, the memory is intrinsically transparent regardless of the density.

Nonvolatility and non-destructive reading: Once set or reset, the memory state remains when unbiased. The reading voltage used (e.g., +1 V or lower) does not affect the stored memory states.

Two-terminal configuration: The set, reset, and read operations may share the same electrodes, as opposed to a three-terminal configurations where reading and programming use different electrodes.

Non-charge based: No degradation was observed for the stored states after X-Ray exposure (dose ˜2 MGy). It shows the non-charge based nature and is potentially useful for radiation hardened electronics.

High ON/OFF ratio: experiments have shown that ON/OFF ratio as high as 1,000,000 can be achieved.

Promising scaling: The active filament involved in functioning is revealed to be at the size of ˜5 nm in diameter or smaller. This is promising for future device scaling to achieve high-density memory.

The use of SiOₓ in electronic devices is discussed further in U.S. patent application Ser. No. 12/240,673 filed Sep. 29, 2008; U.S. patent application Ser. No. 12/270,246 filed Nov. 13, 2008; PCT Application No. PCT/US11/27556 filed Mar. 8, 2011; and PCT Application No. PCT/US11/50812 filed Sep. 8, 2011.

The transparent nonvolatile memory can be used in transparent electronics as the transparent memory medium and/or logic medium. For example, displays with memory may utilize transparent memories embedded in the display itself; memory-containing visors and windscreens for smart “heads-up” displays may utilize the transparent memories; and any other electronics where it is desirable to have a transparent memory medium and/or logic medium may utilize transparent memories.

While other memory units, because of their small sizes, can be invisible to the eye at limited numbers, they inevitably become opaque when the density increases. These other memory units are not transparent because either the memory material itself is not transparent or these memory units require metal/silicon electrodes that are not transparent. In contrast, the transparent memory systems discussed herein utilize transparent memory material(s) providing intrinsic memory effects. Therefore, transparent memory material(s) can be combined with any other transparent (conducting) materials to form fully transparent memory units as described above. This transparency is maintained regardless of the memory density.

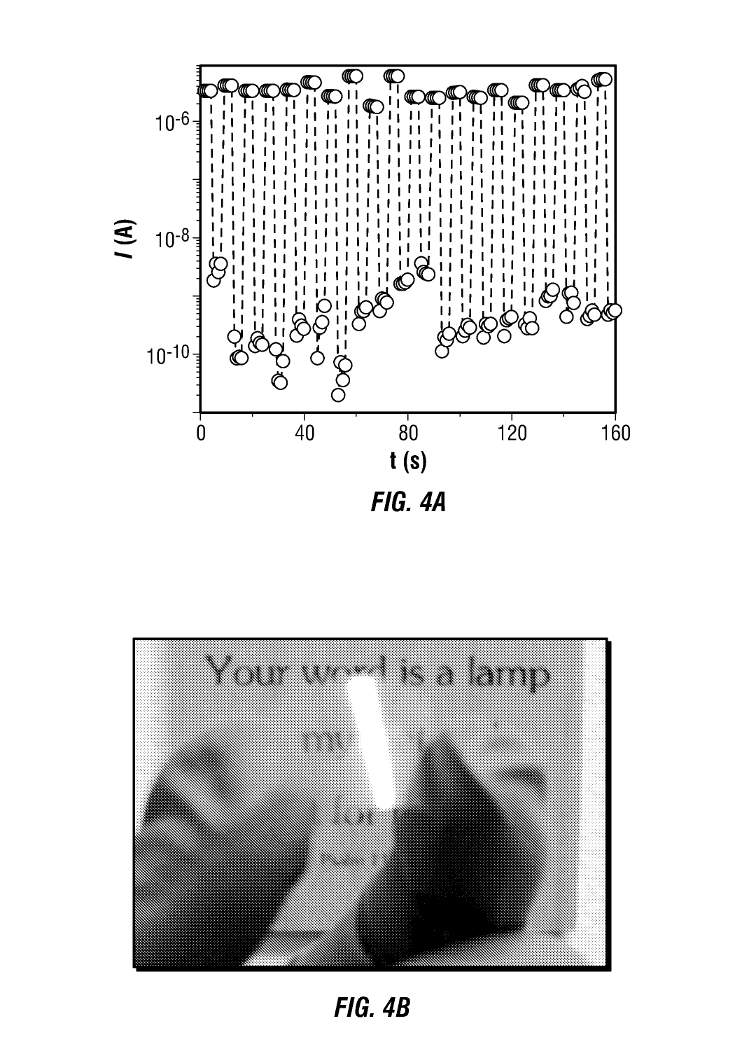

FIG. 4A shows the memory cycles for a TE/TML/TE device; the memory readout was done by +1 V voltage pulses with the programming current not shown. FIG. 4B is an image of invisible memory units on poly(ethylene terephthalate) (PET) plastic. In the image, the reflection of light is the only indication of the memory's presence.

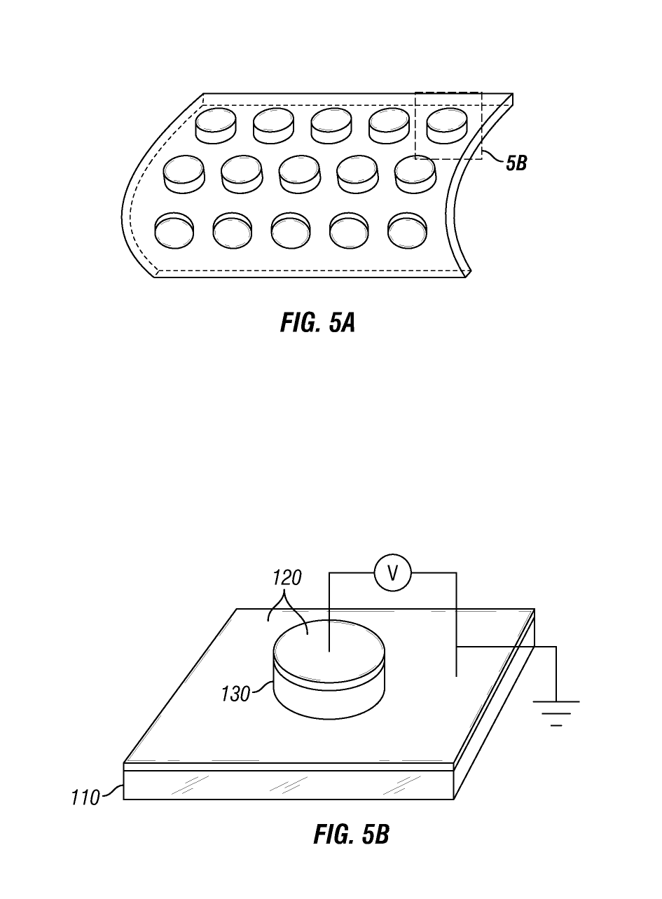

FIG. 5A is an illustrative implementation of a transparent memory system providing multiple memory units on a transparent substrate. FIG. 5B is a close up view of a memory unit from FIG. 5A. The memory provides multiple memory bits that were built on flexible plastic substrate 110 with graphene electrodes 120 sandwiching a SiOₓ layer 130. 20% of the devices provided switching as shown in FIG. 4B. When similarly constructed on a transparent fluoropolymer, the yield was 70%. In some implementations, a transparent memory system may comprise a memory array providing multiple transparent memory units. Such memory arrays may include arrays of memory units in horizontal configurations, planar configurations, crossbar configurations, or any suitable arrangement known in the art for memory units.

### EXPERIMENTAL EXAMPLES

The following experimental examples are included to demonstrate particular aspects of the present disclosure. It should be appreciated by those of ordinary skill in the art that the methods described in the examples that follow merely represent illustrative embodiments of the disclosure. Those of ordinary skill in the art should, in light of the present disclosure, appreciate that many changes can be made in the specific embodiments described and still obtain a like or similar result without departing from the spirit and scope of the present disclosure.

### Example 1

### Material Preparation

The graphene films were synthesized directly on 25-μm-thick copper foils via the chemical vapor deposition (CVD) method. The process began with the thermal annealing of the copper foil at 1035° C. under H₂ flow (500 sccm) for 20 min for grain coarsening. Then at the stabilized temperature of 1035° C. and pressure of 10 Torr, CH₄ precursor gas (4 sccm) was introduced into the growth tube for graphene growth (40 min). The CH₄ flow was turned off and the furnace was permitted to cool to room temperature. Protected with PMMA (poly(methyl methacrylate)), the graphene-coated copper film was then etched in a Fe(NO₃)₃ solution (0.5 M), followed by thoroughly cleaning in a 5% HNO₃ solution and DI water. Then large monolayer graphene film was transferred to a highly doped (<0.005 Ω·cm) silicon substrate with a 300 nm thermal-grown SiO₂ layer. After that, the graphene field effect transistors were fabricated by photolithography.

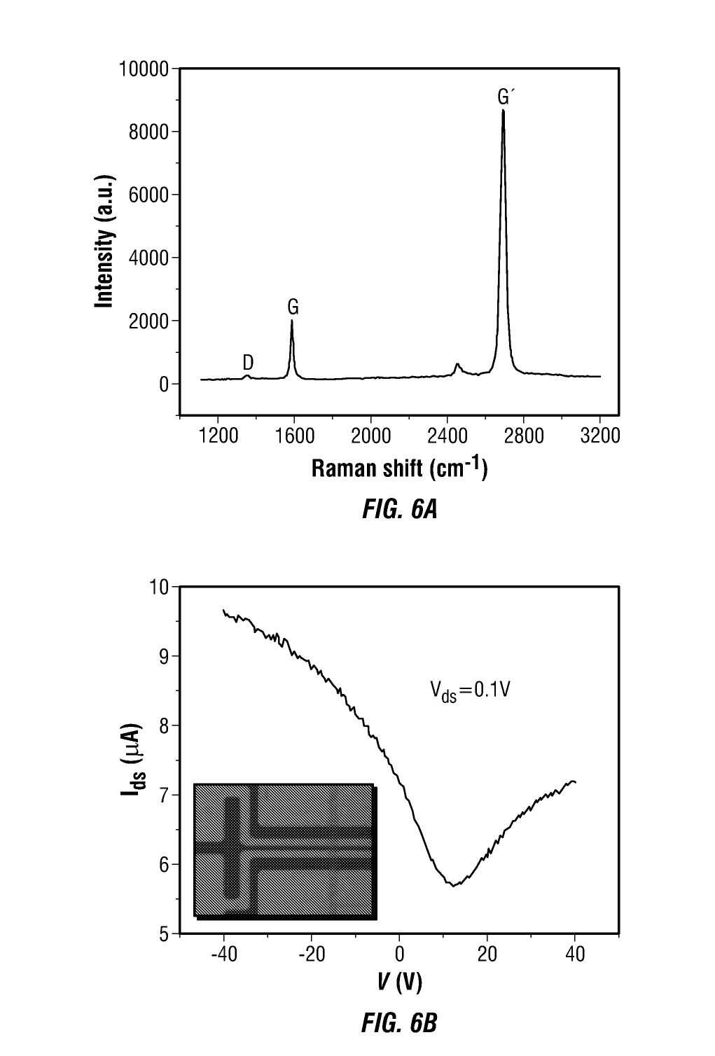

In order to ensure the graphene quality, the spectra and device behavior from the graphene was tested. FIG. 6A shows Raman spectrum of the graphene film grown by the CVD method as described above. The graphene film grown by the CVD method described above was characterized by both Raman spectroscopy (Excitation: 514 nm) and electrical transport measurement. The two pronounced peaks in this spectrum are the G peak at 1,586 cm⁻¹ and the 2D peak at 2,690 cm⁻¹. The I_{2D}/I_{G} ratio is ˜4, indicating that the graphene is a monolayer. The small D peak (1,348 cm⁻¹) indicates the presence of few sp³-carbon atoms or defects. FIG. 6B shows transfer characteristic of a graphene-stripe field effect device. The inset shows optical image of the fabricated device (Scale bar: 20 μm). The transport I-V curve also shows the typical bipolar transport property, with the estimated mobility of 1200 cm² V⁻¹ s⁻¹ for holes and 880 cm² V⁻¹ s⁻¹ for electrons.

### Example 2

### Device Fabrication for G/SiOₓ/ITO Pillar Structure

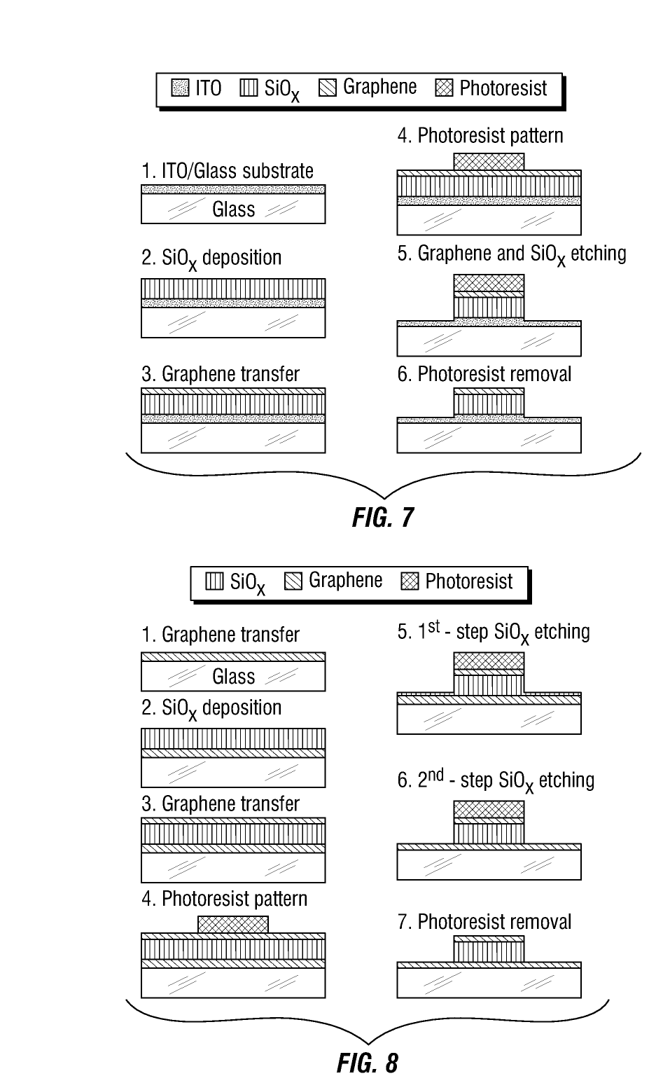

FIG. 7 is a schematic of fabrication process for a G/SiOₓ/ITO device. A glass substrate coated with an ITO layer (120 nm, ˜100 Ω/□ or Ω/square) was used as the starting substrate. A layer of SiOₓ (˜70 nm thick) was deposited by electron beam evaporation. Monolayer graphene film was transferred twice to afford a bilayer on to the SiOₓ/ITO/glass substrate to form the graphene top electrode. For the definition of the circular patterns, photolithography was used to define circular resist (e.g. Microposit S1813) patterns (diameters ˜100 μm) as the sacrificial mask. Reactive ion etching (RIE, using CHF₃/O₂) was used to vertically etch the graphene and SiOₓ layer at the region unprotected by the resist. The photoresist mask was then removed by acetone. Note that an etched vertical SiOₓ edge is desired for the electroforming process and the subsequent memory switching, as the etched surface is expected to be more defected compared to the rest bulk region in the SiOₓ layer and hence provides the localized region for the self-limiting process of silicon-filament formation.

### Example 3

### Device fabrication for G/SiOₓ/G Pillar Structure

FIG. 8 is a schematic of a fabrication process for a G/SiOₓ/G device. To form the layered structure of G/SiOₓ/G, a bilayer-graphene film (using layer-to-layer transferred technique) was first transferred onto the glass substrate. A layer of SiOₓ film with the thickness of 70 nm was deposited by electron beam evaporation. The top bilayer graphene film was then transferred on to the SiOₓ layer. Circular photoresist patterns (diameters ˜100 μm) were then defined by photolithography as described in above G/SiOₓ/ITO. Oxygen plasma was used to etch the top graphene film at the region unprotected by the photoresist mask. RIE (CHF₃/O₂) was used to partially etch the SiOₓ layer followed by further SiOₓ etching by buffered oxide etch (BOE, 10:1). The two-step SiOₓ etching protects the bottom graphene electrodes from RIE etching while still defining the vertical SiOₓ edge that facilitates the electroforming. The photoresist was then removed with acetone. The fabrication of G/SiOₓ/G pillar structures on the plastic substrate followed the similar procedure. In addition, the fluoropolymer (PFA: operational temperature larger than 280° C., such as McMaster, product ID: 84955K16) plastic substrate was treated with oxygen plasma for 90 s to increase its wettability to acetone, prior to the transfer of the bottom bilayer-graphene film. After the oxygen plasma treatment, the measured contact angle with acetone decreased from 69.3° to 25.7°. For easier handling of the plastic substrate, it was fixed on a silicon substrate during the fabrication process.

### Example 4

### Device Fabrication for G/SiOₓ/G Crossbar Structure

For ease of fabrication, the G/SiOₓ/G crossbar structure was fabricated on a silicon substrate (>5000 Ω·cm). The bottom bilayer graphene was first transferred on to the silicon substrate. Photolithography was used to define the resist mask, and then oxygen plasma was employed to etch and define the bottom graphene lines. Metal electrodes (Au/Ti=20 nm/2 nm, 100×100 μm²) were patterned at the end of each graphene line by photolithography, electron-beam evaporation and lift-off processes, serving as the bottom electrical contact for the probe tip. A layer of SiOₓ film (˜70 nm) was then deposited by electron-beam evaporation. The top bilayer graphene film was then transferred on to the SiOₓ layer. Photolithography was used to define the sacrificial layer for the top graphene lines, followed by the two-step SiOₓ etching method described before. Finally, top-metal electrode (Au/Ti=30 nm/5 nm, 100×100 μm²) was also patterned at the end of each top graphene line to form electrical contact for the upper probe tip.

### Example 5

### Electroforming

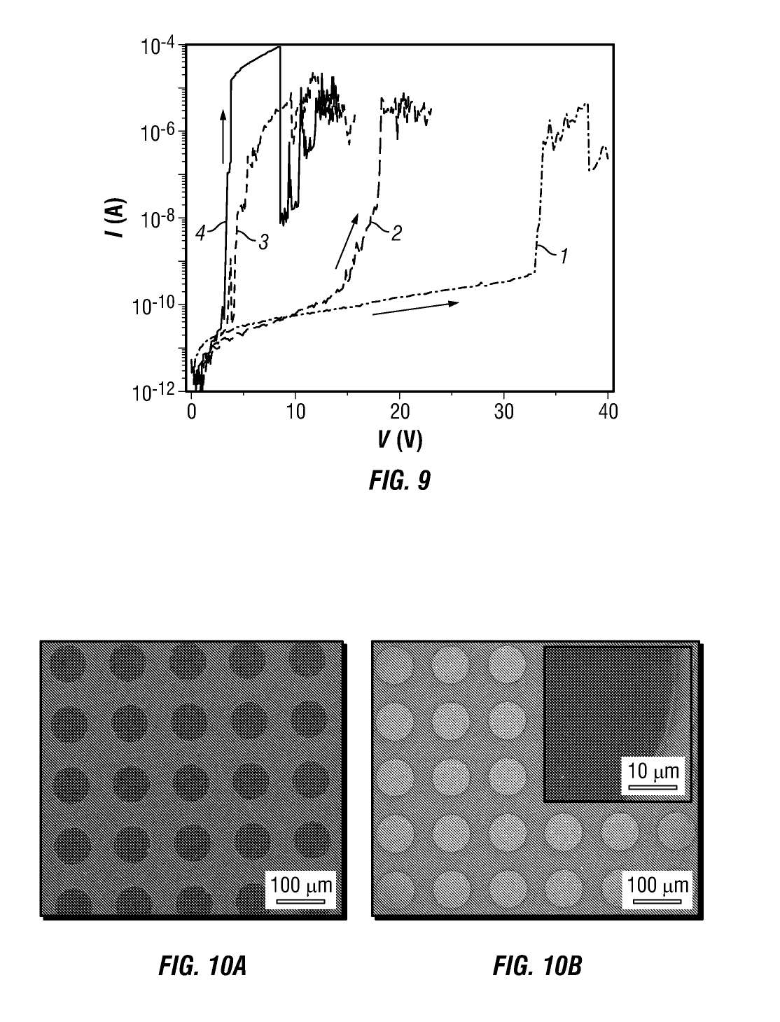

FIG. 9 shows a electroforming process for a vertical G/SiOₓ/ITO device. The numbers near the I-V curves indicate the corresponding sweep orders. The device was initially in a non-conduction state. By a voltage sweep to a high value (e.g., +40 V, curve 1), a sudden current increase (to ˜10⁻⁶ A) was induced at ˜33 V, accompanied by current fluctuations. During the subsequent voltage sweeps (curves 2 and 3), the currents gradually increased, as did the current fluctuations. A characteristic resistive switching I-V (curve 4) then appeared, featuring the sudden current increase and drop defining the set and reset values, respectively. The arrows indicate the voltage sweep directions. This electroforming process is similar to those described in SiOₓ-based resistive switching systems.

FIG. 10A shows SEM images of the G/SiOₓ/ITO devices. FIG. 10B shows SEM images control SiOₓ/ITO devices without the top graphene layers. Over 20 devices were randomly selected for each type of the structures for the electrical characterizations. Around 70% of the G/SiOₓ/ITO devices tested showed memory switching properties as described herein. No switching was observed by directly landing the probe-tip on the SiOₓ layer in the control SiOₓ/ITO devices, hence the top electrode is desirable to provide switching. The inset in FIG. 10B shows an enlarged picture of the SiOₓ-layer surface, showing uniform morphology without observable surface pinholes at this resolution. This ruled out the possibility of metal-filament switching caused by the probe tip in contact with the top electrode and further indicated the edge-localized switching.

As one of the backbones of the semiconductor industry, SiOₓ comes with the advantages in both its material composition and facile processing. With a large bandgap (˜9 eV), it also features high transparency. Instead of merely serving as a passive solid electrolyte in metallic programmable cells, an active role of SiOₓ in constructing resistive switching memory was recently revealed: SiOₓ itself can serve as the source of the formation of metallic-phase silicon filaments as well as the surrounding supportive matrix. The result is a memory effect that is intrinsic to SiOₓ and largely electrode-independent. This intrinsic memory effect in SiOₓ relaxes the restriction on the choice of electrode materials, making high-transparency or invisible memory devices feasible.

Non-limiting examples of transparent conductive materials, such as graphene and ITO, make them suitable for use as transparent electrodes. The combination of the two electrode materials in a single device demonstrates the versatility of the SiOₓ-based memory with respect to the choice of transparent electrode materials.

Vertical sandwiched pillar structures of G/SiOₓ/ITO (here G denotes graphene) were defined on a glass substrate. Specifically, the SiOₓ layer (˜70 nm thick) was prepared by physical vapor deposition (PVD) on a glass substrate coated with a layer of ITO (˜120 nm thick), with the top electrode consisting of bilayer graphene prepared by the chemical vapor deposition method and transfer process. Photolithography and reactive ion etching were then used to define the circular G/SiOₓ/ITO memory units at a diameter of ˜100 μm for an easy probe-tip landing. The electrical characterizations were performed in vacuum (10⁻⁵ Torr) at room temperature in a probe station connected to an Agilent 4155C semiconductor parameter analyzer.

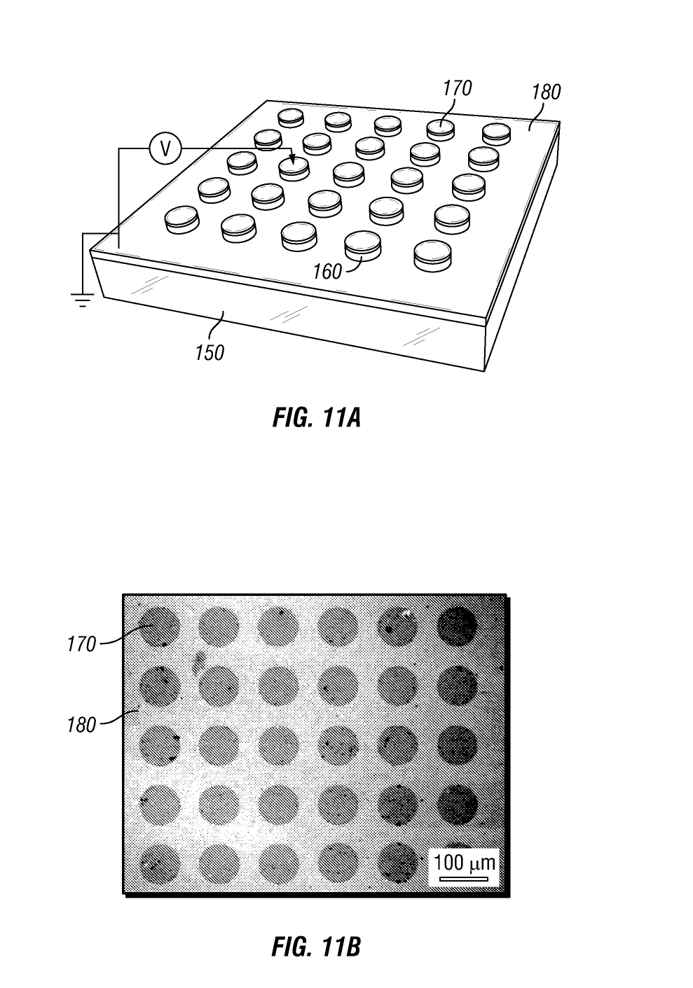

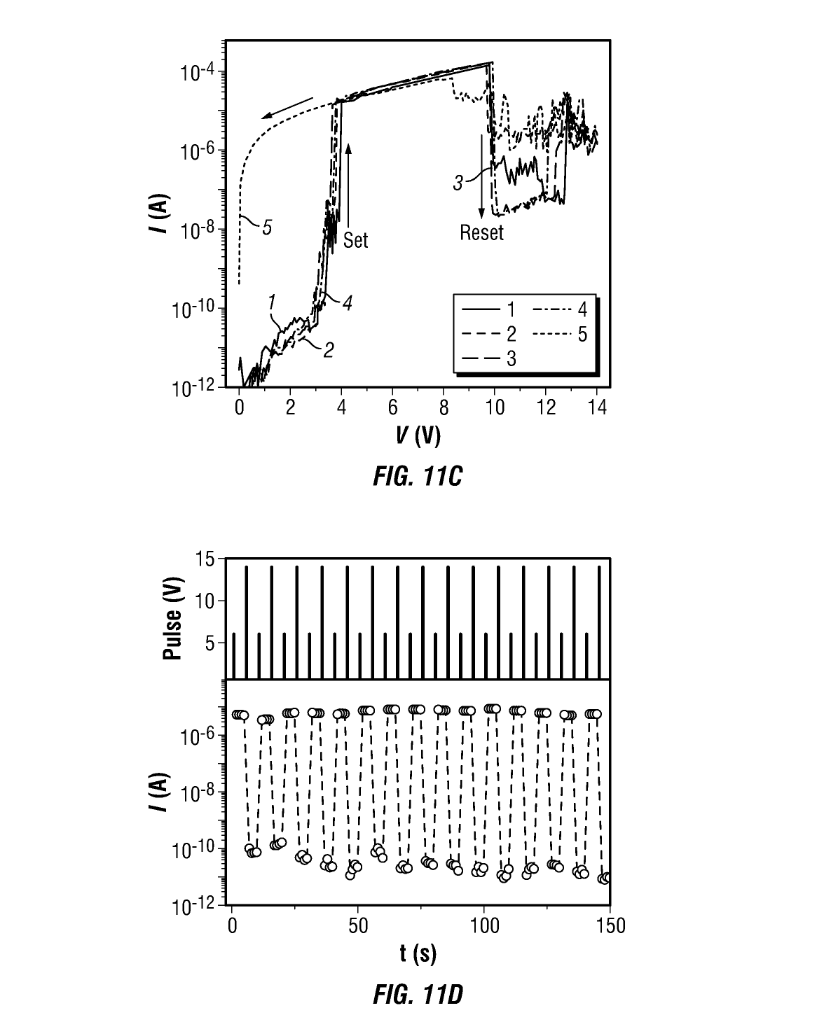

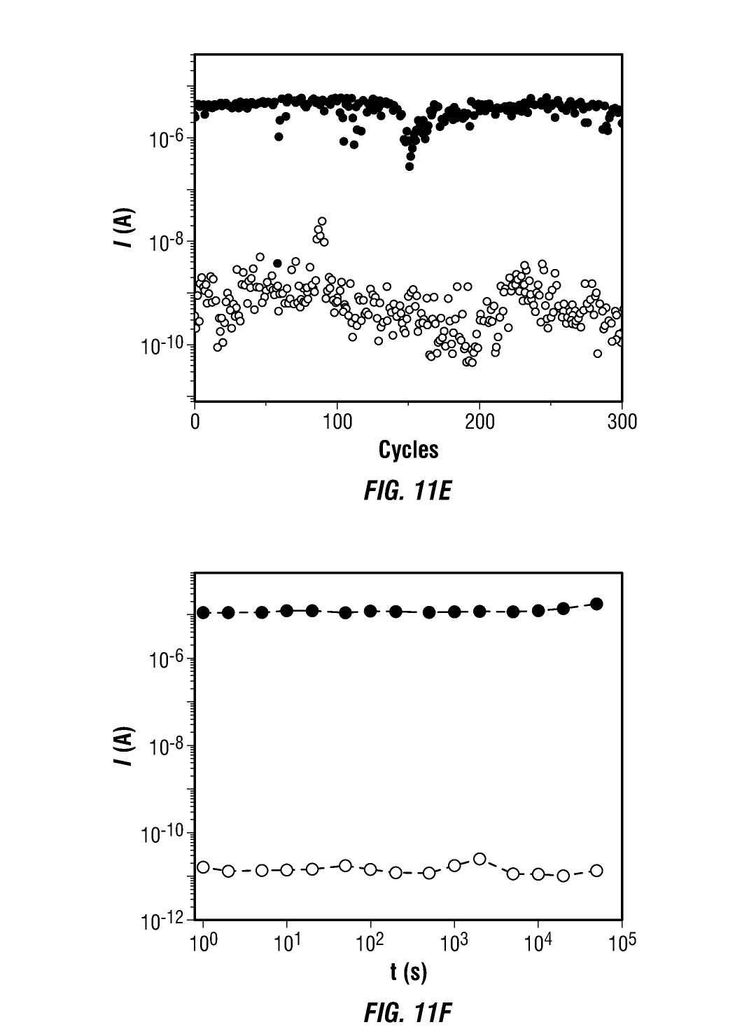

FIG. 11A shows a G/SiOₓ/ITO device arrays on a glass substrate 150 and a setup for electrical characterization. A SiOₓ layer 160 is positioned between a top graphene electrode 170 and a bottom ITO electrode 180. FIG. 11B shows optical images of the G/SiOₓ/ITO devices. FIG. 11C shows I-V curves from an electroformed G/SiOₓ/ITO device, with the arrows indicating the voltage-sweep directions and the numbers indicating the voltage-sweep orders.

FIG. 11C shows a series of current-voltage (I-V) curves from a G/SiOₓ/ITO device after the electroforming process. In the characteristic I-V curve (curve 4), starting from a high-resistance (OFF) state, the current level suddenly increases at ˜4 V to a low-resistance (ON) state and then decreases at ˜10 V. The current or conductance increase and decrease define the set and reset values, respectively, indicating unipolar resistive switching behavior. The resistance or memory state can be read at a low voltage bias (<3 V) without altering its value, featuring the nonvolatile property. FIG. 11D shows a series of voltage pulses of +6 V, +1 V (5 times), and +14 V serve as set, read (5 times), and reset operations, respectively. Below currents corresponding to each read pulse above. FIG. 11E shows 300 memory cycles in a G/SiOₓ/ITO device. FIG. 11F shows retention of the memory state tested by continuous +1 V voltage pulses (at a rate of 1 pulse per sec) for both an ON and an OFF state. FIGS. 11D and 11E shows a series of memory cycles using +1 V, +6 V, and +14 V as read, set, and reset voltages. The nonvolatility or memory retention was tested by continuous memory-state readout at +1 V, which showed no degradation after 5×10⁴ s (FIG. 11F), with an extrapolated retention time beyond years (10⁸ s).

After testing more than 20 devices, a device yield of ˜70% was achieved for the tested memory units, discounting the possibility of contamination-related memory effect; the 30% of non-working devices were short circuited. However, this depressed yield compared to that achieved in devices with polysilicon electrodes is likely caused by the atomically-thin nature of the graphene electrode, as structural damage in the graphene layer might result during the processing and/or the probe-tip landing processes (FIG. 11A). The resultant damage could cause sliding of the graphene electrode and shorting of the devices, thereby lowering the yield. Note that the possibility of extrinsic switching through metal filament formation from the tungsten probe tip in contact with the top electrode was ruled out by control experiments in which memory switching could not be achieved in devices that were devoid of the top graphene electrodes (FIG. 10B).

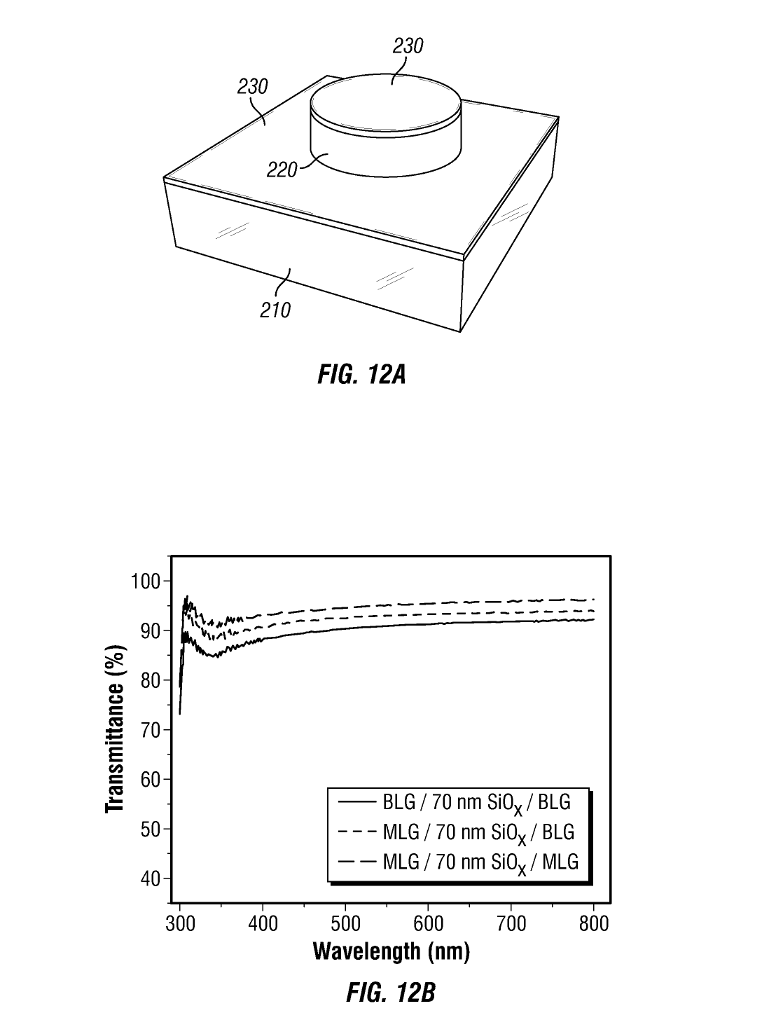

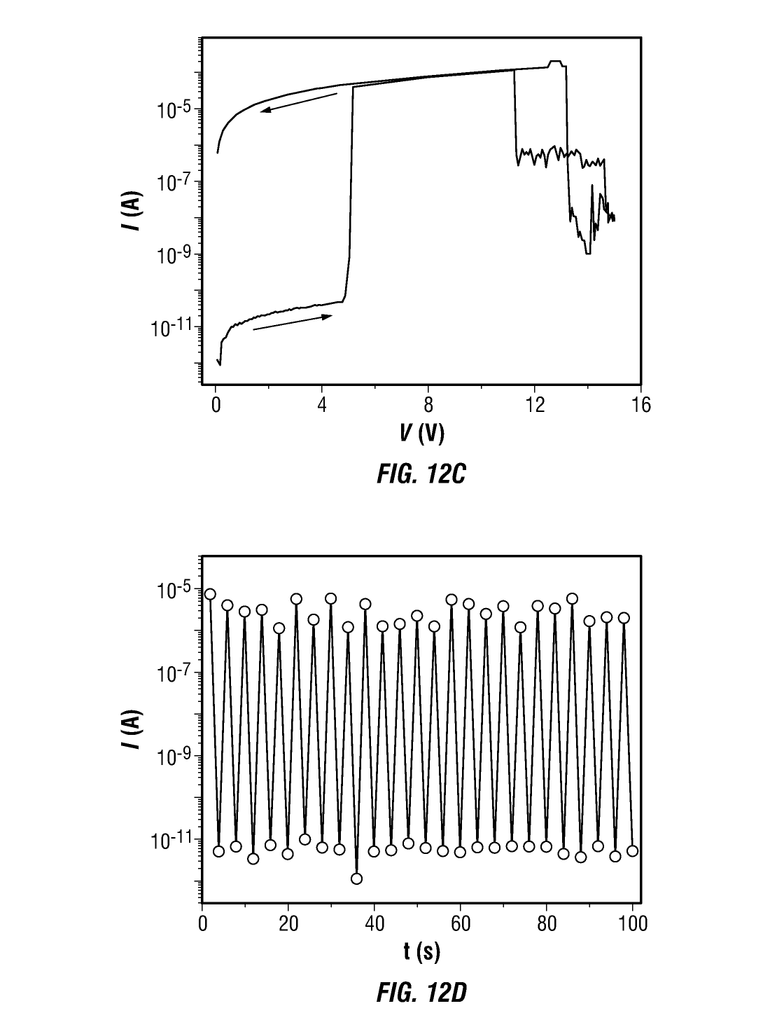

FIG. 12A shows a G/SiOₓ/G device on a glass substrate 210. A SiOₓ layer 220 is positioned between graphene electrodes 230. FIG. 12B shows optical transmittance in G/SiOₓ/G layered structures with different layer thicknesses of graphene. Bilayer graphene (BLG) on top and bottom, monolayer graphene (MLG) top and BLG bottom, and MLG on top and bottom are illustrated. FIG. 12C shows characteristic I-V curves from an electroformed G/SiOₓ/G device. FIG. 12D shows corresponding memory cycles from the device using +6 V and +15 V as set and reset voltages, respectively. The programming current is not shown here and the memory states (current) were recorded at +1 V.

As shown in FIG. 12A, vertical sandwiched pillar structures of G/SiOₓ/G with the same diameters (˜100 μm) were defined on the glass substrate, which shows 90% transparency at 550 nm (FIG. 12B). Specifically, bilayer graphene sheets were used for both the top and bottom electrodes with the SiOₓ thickness ˜70 nm. The devices showed similar resistive switching I-V curves and memory property to those exhibited in FIG. 11C in a yield of 65% with over 20 devices being tested; the 35% non-operating devices being short circuited. The use of graphene as both top and bottom electrodes further indicates the intrinsic memory property of SiOₓ by excluding the possibility of metal filament from the electrode materials.

While graphene and graphene oxide have been used in some resistive switching systems, metal electrodes prevent the transparency of the memory devices. Because of the low optical absorbance in graphene, uniform transmittance as high as ˜90% over the visible range is achieved in the G/SiOₓ/G devices (FIG. 12B). Here, bilayer graphene was used for both the top and bottom electrodes for the purpose of better coverage. It is not due to an intrinsic limit with respect to the resistance. In fact, as the ON-state resistance of SiOₓ is >10 kΩ (FIG. 12D), doped monolayer graphene (<1 kΩ/□ or kΩ/square) is sufficient for serving as the electrode material. As a result, the transmittance can be further increased to ˜95% (MLG/SiOx/MLG curve in FIG. 12B), which is higher and more uniform than those achieved in other systems.

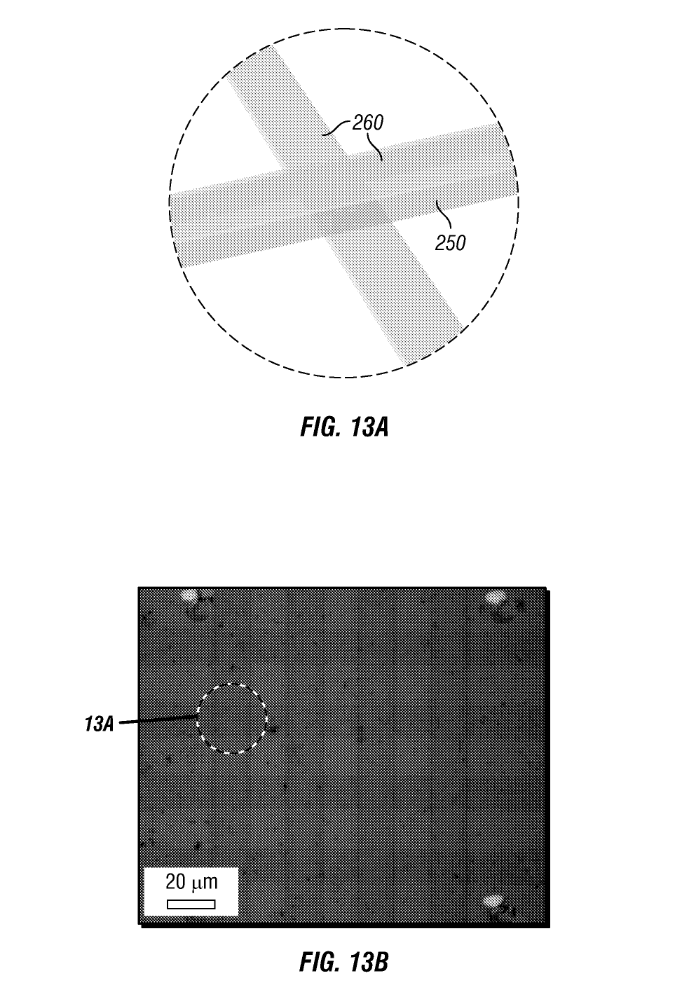

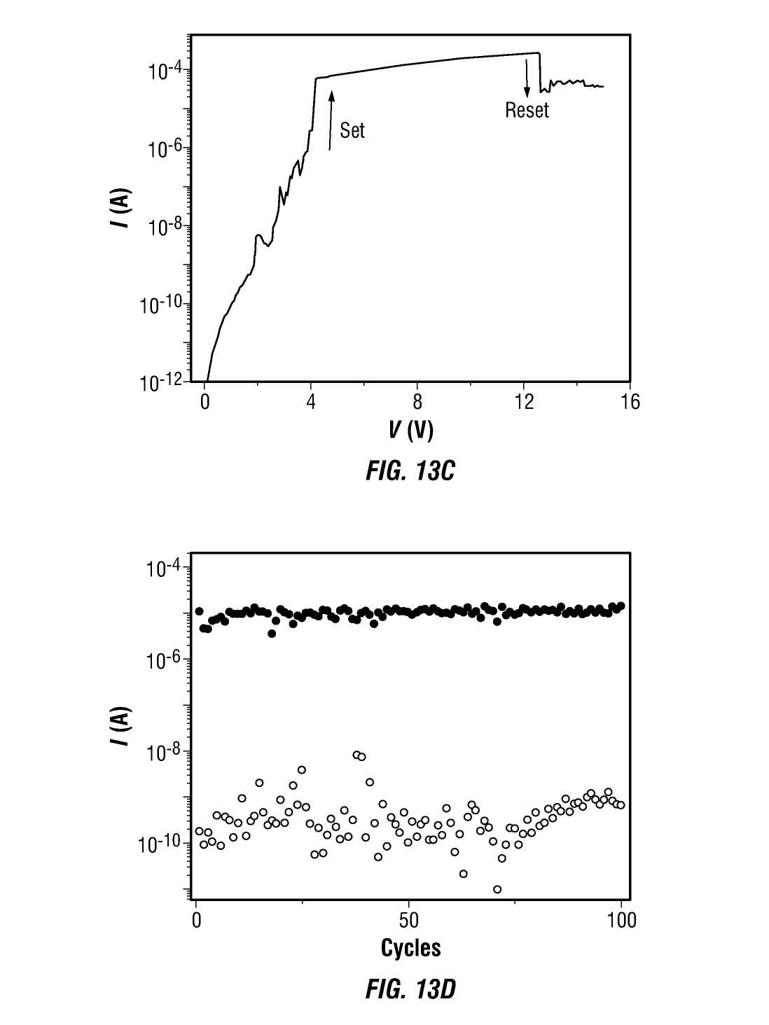

FIG. 13A and FIG. 13B show an enlarged view of a crossbar structure and optical image of a 4×4 G/SiOₓ/G crossbar structure. A SiO, layer 250 is positioned between graphene electrodes 260 in a crossbar arrangement. FIG. 13C shows characteristic I-V curves from an electroformed crossbar memory unit. FIG. 13D shows 100 memory cycles from the device using +5 V and +15 V as set and reset voltages, respectively. The programming current is not shown here and the memory states (current) were recorded at +1 V.

While the vertical pillar structures adopted above are frequently used for single-device testing purpose, other memory device may rely on the construction of memory arrays, such as a crossbar array. We further demonstrate the transparent SiOₓ crossbar memory arrays with graphene serving as both the electrode and interconnect material, in this case constructed atop a silicon/silicon oxide substrate. FIG. 13B shows a 4×4 SiOₓ crossbar structure with the SiOₓ (˜70 nm thick) sandwiched between the top and bottom bilayer graphene lines. FIGS. 13C and 13D show the typical I-V curve and memory switching cycles from one of the crossbar units (20 μm×20 μm), featuring the same switching characteristics as those shown in the vertical pillar structures. The crossbar structure with both the top and bottom electrodes extended through the graphene lines avoids the direct contact between the probe tip and the memory unit during the electrical testing, which eliminates the possibility of metal contamination from the probe tip and hence further confirms the intrinsic memory effects in SiOₓ. This may have also contributed to an increased device yield to ˜80% (16 of 20 devices) due to the absence of damage from the probe tip to the graphene electrodes as discussed before. Despite the 20× reduction in the device area in the memory unit here (FIG. 13A) compared to those in the pillar structures (e.g. FIG. 11A), the current level is maintained (FIG. 13D), indicating the filamentary nature of switching. Indeed, the metallic silicon filament was revealed to be sub-10 nm in size, indicating the potential for aggressive device scaling. This confined nanoscale switching along with the intrinsic transparency shows the possibility of high-density transparent memory applications. The SiOₓ memory here features low programming current levels (˜0.1 mA, FIG. 13C), more than one order of magnitude lower than those in other transparent resistive memory systems. The reduced programming currents bring down the current density in the interconnects, providing more room for the transparent interconnects for an invisible circuit.

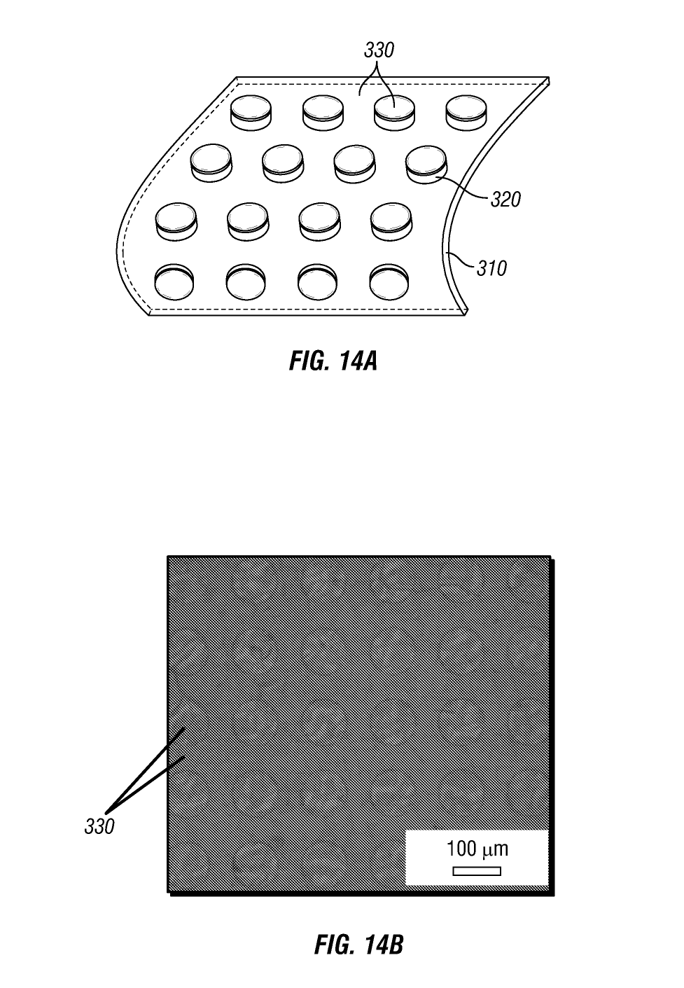

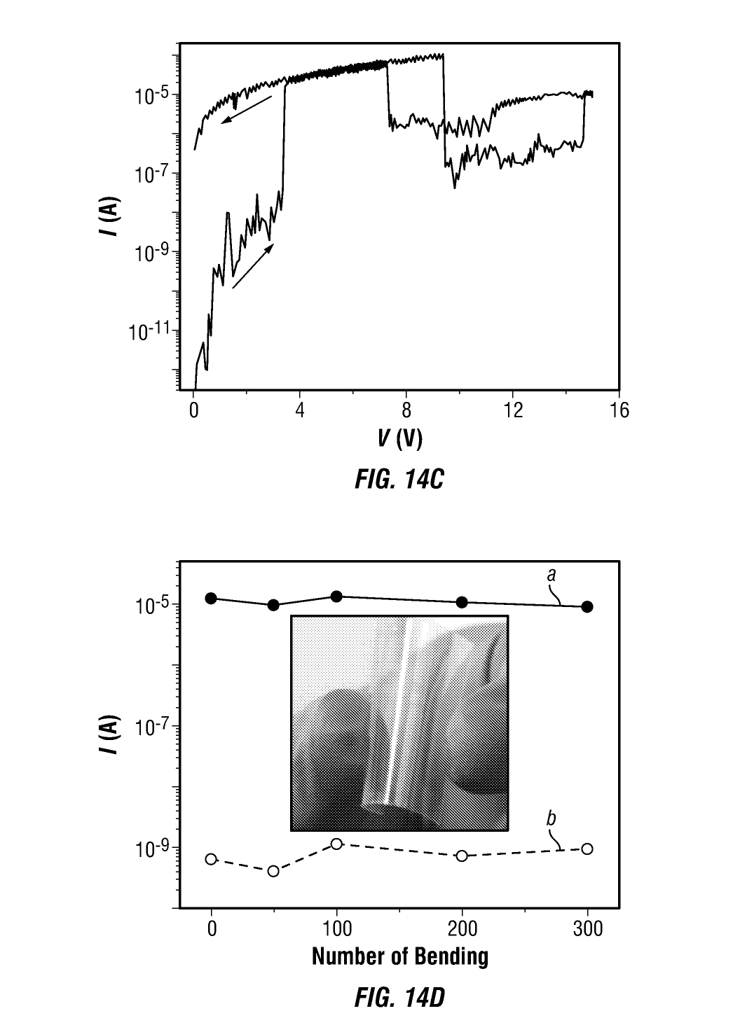

FIGS. 14A and 14B show a G/SiOₓ/G device array on a plastic (fluoropolymer) substrate 310 and an optical image of the arrays. A SiOₓ layer 320 is positioned between graphene electrodes 330. FIG. 14C shows characteristic resistive switching I-V curve from a G/SiOₓ/G device on the plastic substrate. FIG. 14D shows retention of both ON (curve a) and OFF (curve b) memory states (read at +1 V) is shown upon bending the plastic substrate around a ˜1.2-cm diameter curvature; the central devices on the sheet being tested throughout the bending cycles. The inset shows the actual transparent memory devices on the plastic substrate.

The versatile transfer process of graphene to various substrates also enables the fabrication of the memory devices on plastic transparent substrates. Layered structures of G/SiOₓ/G were first deposited on a plastic (fluoropolymer, such as Perfluoroalkoxy (PFA)) substrate by transfer processes and SiOₓ PVD. Photolithography and etching processes were then used to define the vertical pillar structures. Here, a fluoropolymer was chosen as the plastic substrate for its comparatively high melting point (>280° C.) in order to sustain the current local heating involved during the initial electroforming process in the G/SiOₓ/G devices. The electroformed devices showed the same memory switching characteristics (FIG. 14C) as those from devices on rigid substrates, and the yield is about 70%. The memory states showed no degradation upon bending the flexible plastic substrate (FIG. 14D), demonstrating the feasibility of both transparent and flexible memory applications.

In summary, we have demonstrated transparent nonvolatile memory devices featuring high transparency, long retention and low programming currents. For the unique place of SiOₓ in the semiconductor industry and the promising future of graphene as an electrode material, the SiOₓ-graphene memory system features its advantages in both materials composition and processing.

Implementations described herein are included to demonstrate particular aspects of the present disclosure. It should be appreciated by those of skill in the art that the implementations described herein merely represent exemplary implementation of the disclosure. Those of ordinary skill in the art should, in light of the present disclosure, appreciate that many changes can be made in the specific implementations described and still obtain a like or similar result without departing from the spirit and scope of the present disclosure. From the foregoing description, one of ordinary skill in the art can easily ascertain the essential characteristics of this disclosure, and without departing from the spirit and scope thereof, can make various changes and modifications to adapt the disclosure to various usages and conditions. The implementations described hereinabove are meant to be illustrative only and should not be taken as limiting of the scope of the disclosure.

What is claimed is:

1. An optically transparent memory device comprising:
a first electrode, wherein the first electrode is formed from a first conductive material that is transparent;
a resistive memory layer coupled to the first electrode, wherein the resistive memory layer is formed from a resistive memory material that is transparent; and
a second electrode coupled to the resistive memory layer, wherein the second electrode is formed from a second conductive material that is transparent.

2. The device of claim 1, wherein the first and second electrodes are positioned on the resistive memory layer, and the first and second electrodes are separated by a nanogap.

3. The device of claim 1, wherein the resistive memory layer is positioned between the first electrode and the second electrode.

4. The device of claim 1, further comprising a substrate, wherein the substrate is made from an insulating material that is transparent.

5. The device of claim 1, wherein the first conductive material is graphene, indium tin oxide (ITO), a transparent conducting oxide, fluorine doped tin oxide (FTO), doped zinc oxide, aluminum-doped zinc-oxide (AZO), indium-doped cadmium-oxide, a transparent conducting polymer, polyacetylene, polyaniline, polypyrrole, polythiophenes, or a nanocarbon coating.

6. The device of claim 1, wherein the second conductive material is graphene, indium tin oxide (ITO), a transparent conducting oxide, fluorine doped tin oxide (FTO), doped zinc oxide, aluminum-doped zinc-oxide (AZO), indium-doped cadmium-oxide, a transparent conducting polymer, polyacetylene, polyaniline, polypyrrole, polythiophenes, or a nanocarbon coating.

7. The device of claim 1, wherein the resistive memory material is SiOₓ, where x is greater than or equal to 0.5 or less than or equal to 2.

8. The device of claim 1, wherein the resistive memory material is SiOₓN_{y}, where x is greater than or equal to 1 or less than or equal to 2, and y is greater than or equal to 0 or less than or equal to 1.33.

9. The device of claim 1, wherein the resistive memory material is SiOₓC_{z}, where x is greater than or equal to 1 or less than or equal to 2, and z is greater than or equal to 0 or less than or equal to 1.

10. The device of claim 1, wherein the resistive memory material is SiOₓH, SiOₓN_{y}H, SiOₓC_{z}H, wherein 10 each of x, y and z are equal or greater than 1 or equal or less than 2.

11. The device of claim 4, wherein the insulating material is glass, plastic, polymer, fluropolymer, perfluoroalkoxy polymer, poly(ethylene terephthalate), or poly(methyl methacrylate).

12. The device of claim 1, wherein the device has greater than 90% transparency at 550 nm.

13. The device of claim 1, wherein the device has greater than 50% transparency at 550 nm.

14. The device of claim 1, wherein the device has greater than 30% transparency at 550 nm.

15. The device of claim 1, wherein the first electrode or second electrode have greater than about 90% transparency at 550 nm.

16. The device of claim 1, wherein the first electrode or second electrode have greater than about 50% transparency at 550 nm.

17. The device of claim 1, wherein the first electrode or second electrode have greater than about 30% transparency at 550 nm.

18. The device of claim 1, wherein the device is a two terminal memory.

19. The device of claim 1, wherein the resistive memory layer is activated by a series of voltage pulses.

20. The device of claim 1, wherein the optically transparent memory device is part of a crossbar array.

21. The device of claim 1, wherein the optically transparent memory device is nonvolatile.

22. The device of claim 1, wherein the optically transparent memory device is integrated with a display, touch screen display, smart window, CMOS transistors, microelectronic device, nanoelectronic device.

23. A method for forming an optically transparent memory device, the method comprising:
forming a first electrode from a first conductive material that is transparent;
forming a second electrode from a second conductive material that is transparent; and
forming a resistive memory layer coupled to the first and second electrodes, wherein the resistive memory layer is formed from a resistive memory material that is transparent.

24. The method of claim 23, wherein the first and second electrodes are positioned on the resistive memory layer, and the first and second electrodes are separated by a nanogap.

25. The method of claim 23, wherein the resistive memory layer is positioned between the first electrode and the second electrode.

26. The method of claim 23, further comprising forming a substrate positioned, wherein the substrate is made from an insulating material that is transparent.

27. The method of claim 23, wherein the first conductive material is graphene, indium tin oxide (ITO), a transparent conducting oxide, fluorine doped tin oxide (FTO), doped zinc oxide, aluminum-doped zinc-oxide (AZO), indium-doped cadmium-oxide, a transparent conducting polymer, polyacetylene, polyaniline, polypyrrole, polythiophenes, or a nanocarbon coating.

28. The method of claim 23, wherein the second conductive material is graphene, indium tin oxide (ITO), a transparent conducting oxide, fluorine doped tin oxide (FTO), doped zinc oxide, aluminum-doped zinc-oxide (AZO), indium-doped cadmium-oxide, a transparent conducting polymer, polyacetylene, polyaniline, polypyrrole, polythiophenes, or a nanocarbon coating.

29. The method of claim 23, wherein the resistive memory material is SiOₓ, where x is greater than or equal to 0.5 or less than or equal to 2.

30. The method of claim 23, wherein the resistive memory material is SiOₓN_{y}, where x is greater than or equal to 1 or less than or equal to 2, and y is greater than or equal to 0 or less than or equal to 1.33.

31. The method of claim 23, wherein the resistive memory material is SiOₓC_{z}, where x is greater than or equal to 1 or less than or equal to 2, and z is greater than or equal to 0 or less than or equal to 1.

32. The method of claim 23, wherein the resistive memory material is SiOₓH, SiOₓN_{y}H, SiOₓC_{z}H, wherein each of x, y and z are equal or greater than 1 or equal or less than 2.

33. The method of claim 26, wherein the insulating material is glass, plastic, polymer, fluropolymer, perfluoroalkoxy, poly(ethylene terephthalate), or poly(methyl methacrylate).

34. The method of claim 23, wherein the device has greater than 90% transparency at 550 nm.

35. The method of claim 23, wherein the device has greater than 50% transparency at 550 nm.

36. The method of claim 23, wherein the device has greater than 30% transparency at 550 nm.

37. The method of claim 23, wherein the first electrode or second electrode have greater than about 90% transparency at 550 nm.

38. The method of claim 23, wherein the first electrode or second electrode have greater than about 50% transparency at 550 nm.

39. The method of claim 23, wherein the first electrode or second electrode have greater than about 30% transparency at 550 nm.

40. The method of claim 23, wherein the device is a two terminal memory.

41. The method of claim 23, further comprising activating the resistive memory layer by applying a series of voltage pulses to the first and second electrodes.

42. The method of claim 23, wherein the optically transparent memory device is part of a cross-bar array.

43. The method of claim 23, wherein the optically transparent memory device is integrated with a display, touch screen display, smart window, CMOS transistors, microelectronic device, nanoelectronic device.

44. The method of claim 23, wherein the optically transparent memory device is nonvolatile.
